(19) United States
(12) Patent Application Publication
(10) Pub. No.: US 2018/0072019 A1
(43) Pub. Date: Mar. 15, 2018

(54) CONDUCTIVE SUBSTRATE

(71) Applicant: SUMITOMO METAL MINING CO., LTD., Tokyo (JP)

(72) Inventors: Takumi SHIMOJI, Niihama-shi, Ehime (JP); Junichi NAGATA, Niihama-shi, Ehime (JP)

(21) Appl. No.: 15/563,702

(22) PCT Filed: Apr. 21, 2016
(86) PCT No.: PCT/JP2016/062673

§ 371 Date: Oct. 2, 2017

(30) Foreign Application Priority Data
Apr. 28, 2015 (JP) 2015-091714

(51) Int. Cl. B32B 7/02; C23C 14/08; H01B 5/14; H05K 1/09; C22C 19/03; C23C 14/34; H05K 3/06

(52) U.S. Cl. CPC B32B 7/02; C23C 14/08; H01B 5/14; C23C 22/68; C22C 19/03; C23C 14/34; H05K 3/06; H05K 1/09

(57) ABSTRACT

A conductive substrate is provided that includes a transparent base material, a metal layer formed on at least one surface of the transparent base material, and a blackened layer formed on at least one surface of the transparent base material. The blackened layer contains elemental copper and/or a copper compound, and elemental nickel and a nickel compound. The nickel compound includes a nickel oxide and a nickel hydroxide.

### TECHNICAL FIELD

The present invention relates to a conductive substrate.

### BACKGROUND ART

A transparent conductive film for a touch panel having an ITO (indium-tin oxide) film formed as a transparent conductive film on a polymer film as described in Patent Document 1 has been conventionally used.

In recent years, the screens of displays provided with touch panels are becoming increasingly larger, and as such, there is a demand for increasing the size of conductive substrates, such as transparent conductive films for touch panels. However, increasing the size of conductive substrates has been difficult owing to the high electrical resistance of ITO.

In this respect, use of a metal foil such as copper instead of an ITO film has been contemplated as described in Patent Documents 2 and 3, for example. However, when a metal foil is used in place of an ITO film, for example, because a metal foil has metallic luster, visibility of the display may be degraded due to light reflection.

Accordingly, a conductive substrate having a metal layer made of copper or the like and a blackened layer made of a black material formed thereon is being contemplated.

### PRIOR ART DOCUMENTS

### Patent Documents

Patent Document 1: Japanese Unexamined Patent Publication No. 2003-151358
Patent Document 2: Japanese Unexamined Patent Publication No. 2011-018194
Patent Document 3: Japanese Unexamined Patent Publication No. 2013-069261

### SUMMARY OF THE INVENTION

### Problem to be Solved by the Invention

In order to obtain a conductive substrate having a wiring pattern, after a metal layer and a blackened layer are formed, a desired pattern has to be formed by etching the metal layer and the blackened layer. However, the metal layer and the blackened layer may have very different reactivity to an etching solution. As such, when the metal layer and the blackened layer are etched simultaneously, one of the layers may not be etched into a desired pattern, or in-plane uniform etching of the layers may not be achieved to thereby result in dimensional variations, for example. Such problems have been obstacles to performing simultaneous etching of the metal layer and the blackened layer.

In view of the above problems of the related art, it is an object of one aspect of the present invention to provide a conductive substrate including a metal layer and a blackened layer that can be etched simultaneously.

### Means for Solving the Problem

According to an aspect of the present invention, a conductive substrate is provided that includes a transparent base material, a metal layer formed on at least one surface of the transparent base material, and a blackened layer formed on at least one surface of the transparent base material. The blackened layer contains elemental copper and/or a copper compound, and elemental nickel and a nickel compound. The nickel compound includes a nickel oxide and a nickel hydroxide.

### Advantageous Effect of the Invention

According to an aspect of the present invention, a conductive substrate including a metal layer and a blackened layer that can be etched simultaneously may be provided.

### BRIEF DESCRIPTION OF THE DRAWINGS

FIG. 1A is a cross-sectional view of a conductive substrate according to an embodiment of the present invention;

FIG. 1B is a cross-sectional view of a conductive substrate according to an embodiment of the present invention;

FIG. 2A is a cross-sectional view of a conductive substrate according to an embodiment of the present invention;

FIG. 2B is a cross-sectional view of a conductive substrate according to an embodiment of the present invention;

FIG. 3 is a top view of a conductive substrate having a meshed wiring according to an embodiment of the present invention;

FIG. 4A is a cross-sectional view across line A-A′ of FIG. 3;

FIG. 4B is a cross-sectional view across line A-A′ of FIG. 3; and

FIG. 5 is a diagram showing a roll-to-roll sputtering apparatus.

### EMBODIMENTS FOR IMPLEMENTING THE INVENTION

In the following, embodiments of a conductive substrate and a method of fabricating a conductive substrate according to the present invention are described.

(Conductive Substrate)

A conductive substrate according to an embodiment of the present invention may include a transparent base material, a metal layer formed on at least one surface of the transparent base material, and a blackened layer formed on at least one surface of the transparent base material. The blackened layer contains elemental copper and/or a copper compound, and elemental nickel and a nickel compound. The nickel compound may include a nickel oxide and nickel hydroxide.

Note that the conductive substrate according to the present embodiment includes a substrate having a metal layer and a blackened layer formed on a transparent base material surface in a state before the metal layer and the like are patterned, and a substrate after the metal layer and the like are patterned, namely, a wired substrate. The conductive substrate including the metal layer and the blackened layer that have been patterned is a transparent conductive film that includes regions of the transparent base material that are not covered by the metal layer and the like and can therefore transmit light.

In the following, members included in the conductive substrate according to the present embodiment will be described.

The transparent base material is not particularly limited, and an insulating film that transmits visible light, a glass substrate, or the like can be suitably used, for example.

Examples of an insulating film that transmits visible light that may be suitably used include a resin film, such as a polyamide film, a polyethylene terephthalate film, a polyethylene naphthalate film, a cycloolefin film, a polyimide film, and a polycarbonate film. In particular, polyamide, PET (polyethylene terephthalate), COP (cycloolefin polymer), PEN (polyethylene naphthalate), polyimide, polycarbonate and the like may be suitably used as the material of the insulator film that transmits visible light.

The thickness of the transparent base material is not particularly limited and can be selected in view of the required strength, the electrostatic capacity, and the light transmittance of the conductive substrate, for example. The thickness of the transparent base material may be greater than or equal to 10 μm and less than or equal to 200 μm, for example. In particular, when used for touch panel applications, the thickness of the transparent substrate may preferably be greater than or equal to 20 μm and less than or equal to 120 μm, and more preferably greater than or equal to 20 μm and less than or equal to 100 μm, for example. When used for touch panel applications, and particularly for applications requiring a reduced thickness of the overall display, the thickness of the transparent base material may preferably be greater than or equal to 20 μm and less than or equal to 50 μm, for example.

The transparent base material preferably has a relatively high total light transmittance, and for example, the total light transmittance may preferably be greater than or equal to 30%, and more preferably greater than or equal to 60%. When the total light transmittance of the transparent base material is within the above range, visibility of the display can be sufficiently secured when the transparent base material is used for a touch panel application, for example.

The total light transmittance of the transparent base material can be evaluated by the method specified in JIS K 7361-1.

In the following, the metal layer will be described.

The material constituting the metal layer is not particularly limited, and a material having electrical conductivity suitable for the application can be selected. However, from the viewpoint of excellent electrical characteristics and ease of etching, copper is preferably used as the material constituting the metal layer. That is, the metal layer preferably contains copper.

In the case where the metal layer contains copper, the material constituting the metal layer may be, for example, a copper alloy made up of Cu and at least one type of metal selected from a group consisting of Ni, Mo, Ta, Ti, V, Cr, Fe, Mn, Co, and W; or a material containing copper and at least one type of metal selected from the above metals. Also, the metal layer may be a copper layer made of copper, for example.

The method of forming the metal layer is not particularly limited, but in order to avoid a decrease in light transmittance, the metal layer is preferably formed without applying an adhesive between the metal layer and another member. That is, the metal layer is preferably formed directly on the upper surface of another member. Note that the metal layer may be formed on the upper surface of the blackened layer or the transparent base material. Thus, the metal layer is preferably formed directly on the upper surface of the blackened layer or the transparent base material.

Because the metal layer is directly formed on the upper surface of another member, the metal layer preferably includes a metal thin film layer formed by a dry plating method. Although the dry plating method used is not particularly limited, for example, a vapor deposition method, a sputtering method, or an ion plating method may be used, for example. In particular, a sputtering method is preferably used in view of enabling easy control of the film thickness.

To increase the thickness of the metal layer, a layer may be laminated by wet plating after dry plating. Specifically, for example, a metal thin film layer may be formed on the transparent base material or the blackened layer by a dry plating method, and a metal plating layer may be formed by electroplating, which is a type of a wet plating method, using the metal thin film layer as a power feeding layer.

In the case where the metal layer is formed only by the dry plating method as described above, the metal layer may be made up of the metal thin film layer. In the case where the metal layer is formed by a combination of a dry plating method and a wet plating method, the metal layer may be made up of a metal thin film layer and a metal plating layer.

As described above, by forming the metal layer by a dry plating method or a combination of a dry plating method and a wet plating method, the metal layer can be directly formed on the transparent base material or the blackened layer without applying an adhesive.

The thickness of the metal layer is not particularly limited and can be selected in view of the magnitude of the current supplied to the metal layer when it is used as a wiring and the wiring width, for example.

However, when the thickness of the metal layer increases, more time is required to etch the metal layer to form a wiring pattern, and as a result, side etching may be more liable to occur and forming a thin line may become difficult, for example. As such, the thickness of the metal layer is preferably less than or equal to 5 μm, and more preferably less than or equal to 3 μm.

Also, from the viewpoint of lowering the resistance value of the conductive substrate and allowing sufficient supply of electric current, for example, the thickness of the metal layer is preferably greater than or equal to 50 nm, more preferably greater than or equal to 60 nm, and more preferably greater than or equal to 150 nm.

In the case where the metal layer includes the metal thin film layer and the metal plating layer as described above, the total thickness of the metal thin film layer and the metal plating layer is preferably within the above range.

The thickness of the metal thin film layer is not particularly limited regardless of whether the metal layer is made up of the metal thin film layer or whether the metal layer is made up of the metal thin film layer and the metal plating layer. However, in either case, the thickness of the metal thin film layer is preferably greater than or equal to 50 nm and less than or equal to 500 nm, for example.

In the following, the blackened layer will be described.

Because the metal layer has metallic luster, when the wiring of a conductive substrate is formed by merely etching the metal layer formed on a transparent base material, the wiring reflects light, and as a result, visibility of a display may be degraded when the conductive substrate is used as a wiring substrate for a touch panel, for example. In this respect, a method of providing a blackened layer has been contemplated. However, the reactivity of the metal layer and the reactivity of the blackened layer with respect to an etching solution may be greatly different in some cases. As such, when the metal layer and the blackened layer are etched simultaneously, the metal layer and the blackened layer may not be etched into desired shapes, and dimensional variations may occur, for example. For this reason, the metal layer and the blackened layer of a conductive substrate typically have to be etched in separate processes, and it has been difficult to etch the metal layer and the blackened layer simultaneously, that is, in one process.

In this respect, the inventors of the present invention have investigated techniques for developing a blackened layer that can be etched simultaneously with the metal layer, namely, a blackened layer with desirably high reactivity to an etching solution that can be patterned into a desired shape even when etched simultaneously with the metal layer and is less susceptible to dimensional variations. The inventors have conceived the present invention by discovering that the reactivity of the blackened layer to an etching solution may be substantially the same as that of the metal layer when the blackened layer contains elemental copper and/or a copper compound, and elemental nickel and a nickel compound, where the nickel compound includes a nickel oxide and a nickel hydroxide.

As described above, the blackened layer of a conductive substrate according to the present embodiment may contain elemental copper and/or a copper compound, and elemental nickel and a nickel compound, where the nickel compound includes a nickel oxide and nickel hydroxide. Note that the copper compound contained in the blackened layer is not particularly limited but may be, for example, a copper oxide and/or a copper hydroxide. Accordingly, the blackened layer may contain, for example, elemental nickel, a nickel oxide, and a nickel hydroxide, and further contain one or more substances selected from the group consisting of elemental copper, a copper oxide, and a copper hydroxide.

By arranging the blackened layer to contain a nickel oxide, the blackened layer becomes a color that can limit light reflection at the surface of the metal layer to thereby exhibit the function of the blackened layer. Further, by arranging the blackened layer to contain a copper compound, light reflection at the surface of the metal layer can be reduced and the function of the blackened layer can be enhanced.

Further, by arranging the blackened layer to contain nickel hydroxide, the reactivity of the blackened layer with respect to an etching solution can be enhanced, and the reactivity to the etching solution can be substantially the same as that of the metal layer.

The proportion of each component contained in the blackened layer is not particularly limited and can be selected in view of requirements of the conductive substrate, such as the extent to which light reflection has to be reduced and the extent to which reactivity to the etching solution has to be enhanced. However, based on investigations made by the inventors of the present invention, from the viewpoint of sufficiently enhancing the reactivity of the blackened layer to the etching solution, for example, a nickel hydroxide is preferably contained in the blackened layer to the extent that it can be identified as a peak when the blackened layer is measured by X-ray photoelectron spectroscopy (XPS).

In particular, when the blackened layer is measured by X-ray photoelectron spectroscopy (XPS), the following Ni 2p3/2 spectrum peak intensity ratio is preferably exhibited. Provided the peak intensity of elemental nickel is 100, the peak intensity of nickel oxide is preferably greater than or equal to 70 and less than or equal to 80, and the peak intensity of nickel hydroxide is preferably greater than or equal to 65. That is, by arranging the blackened layer to contain a nickel oxide and nickel hydroxide at predetermined ratios with respect to elemental nickel, namely, metallic nickel, both the function of the blackened layer for reducing light reflection and the reactivity of the blackened layer with respect to the etching solution can be improved.

The method for forming the blackened layer is not particularly limited, and any method can be selected as long as the blackened layer can be formed to contain each of the above-mentioned components. However, a sputtering method is preferably used in view of enabling relatively easy control of the composition of the blackened layer to contain each of the above-mentioned components.

Also, the blackened layer is preferably formed directly on the upper surface of another member, such as the transparent base material or the metal layer without using an adhesive. By forming the blackened layer using a dry plating method, the blackened layer can be directly formed on the upper surface of another member without using an adhesive. Thus, the sputtering method is preferably used as the film formation method of the blackened layer from this perspective as well.

In the case of forming the blackened layer of the conductive substrate according to the present embodiment using a sputtering method, an alloy containing nickel and copper can be used as a sputtering target, for example. Note that when the blackened layer does not contain a metal other than nickel and copper as a component, an alloy made up of nickel and copper can be used as the sputtering target.

The blackened layer may be formed by performing the sputtering method using the above sputtering target while supplying oxygen gas and water vapor into a chamber. In this way, the blackened layer containing, as the nickel compound, a nickel oxide derived from the oxygen gas supplied into the chamber and the nickel included in the sputtering target, and a nickel hydroxide derived from the water vapor supplied into the chamber and the nickel included in the sputtering target may be formed.

At this time, the proportion of the components contained in the blackened layer can be selectively controlled by selecting the ratio of the oxygen gas to the water vapor to be supplied into the chamber.

In particular, an inert gas, oxygen gas, and water vapor are preferably supplied simultaneously into the chamber and their respective partial pressures are adjusted so that the amounts of oxygen and water vapor supplied to the blackened layer may be easily adjusted. Also, the water vapor can be supplied as a gas mixture of the inert gas and water.

When forming the blackened layer in the above-described manner, the gas supply ratio of the inert gas, the oxygen gas, and the water vapor to be supplied to the chamber is not particularly limited and can be selected in view of the target composition of the blackened layer, for example.

In a preferred example, gas supply conditions may be selected by performing a preliminary test of measuring a blackened layer that has been formed by X-ray photoelectron spectroscopy (XPS) and adjusting the gas supply conditions so that the Ni 2p3/2 spectrum peak intensity ratio may be within the above-mentioned preferable intensity ratio.

The thickness of the blackened layer is not particularly limited and can be selected in view of requirements of the conductive substrate, such as the extent to which light reflection has to be reduced, for example.

The thickness of the blackened layer is preferably greater than or equal to 20 nm, and more preferably greater than or equal to 30 nm, for example. The blackened layer has a function of reducing light reflection by the metal layer. However, if the blackened layer is too thin, light reflection by the metal layer may not be sufficiently controlled. On the other hand, by arranging the thickness of the blackened layer to be greater than or equal to 20 nm, light reflection at the surface of the metal layer can reliably controlled.

Also, although there is no particular upper limit to the thickness of the blackened layer, if the blackened layer is thicker than necessary, the etching time required for forming the wiring becomes longer to thereby lead to a cost increase. As such, the thickness of the blackened layer is preferably less than or equal to 100 nm, and more preferably less than or equal to 50 nm.

In the following, example configurations of the conductive substrate will be described.

As described above, the conductive substrate according to the present embodiment may include a transparent base material, a metal layer, and a blackened layer. In this case, the order in which the metal layer and the blackened layer are laminated on the transparent base material is not particularly limited. Also, multiple metal layers and blackened layers may be formed. However, in order to limit light reflection at the metal layer surface, the blackened layer is preferably arranged on the surface of the metal layer that is desirably controlled to limit light reflection. In the case where light reflection at the surface of the metal layer needs to be strictly controlled, the blackened layer may be formed on both the upper and lower surfaces of the metal layer, that is, the metal layer may be interposed between two blackened layers, for example.

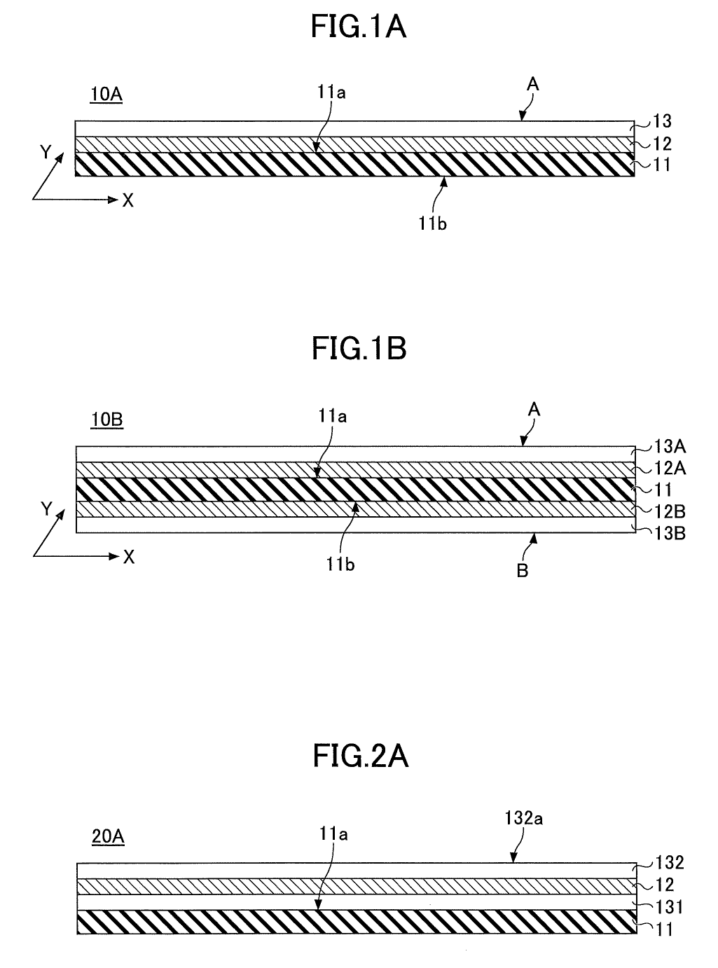

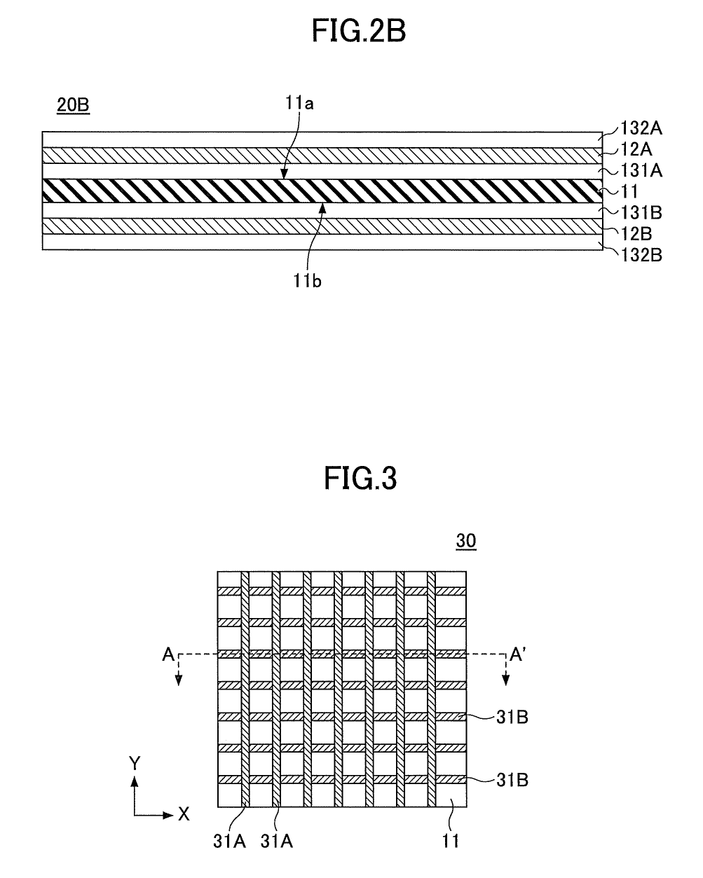

In the following, specific configuration examples will be described with reference to FIG. 1A, FIG. 1B, FIG. 2A, and FIG. 2B. FIG. 1A, FIG. 1B, FIG. 2A, and FIG. 2B are example cross-sectional views of the conductive substrate according to the present embodiment on a plane parallel to the lamination direction of the transparent base material, the metal layer, and the blackened layer.

The conductive substrate according to the present embodiment may have a metal layer and a blackened layer successively laminated in the above recited order on at least one surface of the transparent base material, for example.

Specifically, for example, as in a conductive substrate 10A shown in FIG. 1A, a metal layer 12 and a blackened layer 13 may be successively laminated on one surface 11a of a transparent base material 11 in the above recited order. Further, as in a conductive substrate 10B shown in FIG. 1B, metal layers 12A and 12B and blackened layers 13A and 13B may respectively be laminated on the one surface 11a and another surface (other surface) 11b of the transparent base material 11 in the above recited order. Note that the order in which the metal layer 12 (12A, 12B) and the blackened layer 13 (13A, 13B) are laminated is not limited to the examples of FIGS. 1A and 1B, and in other examples, the blackened layer 13 (13A, 13B) may be laminated on the transparent base material 11 followed by the metal layer 12 (12A, 12B).

Also, for example, multiple blackened layers may be arranged on one surface of the transparent base material 11. In this case, for example, a blackened layer, a metal layer, and a blackened layer may be successively formed on at least one surface of the transparent base material in the above recited order.

Specifically, for example, as in a conductive substrate 20A shown in FIG. 2A, a first blackened layer 131, the metal layer 12, and a second blackened layer 132 may be successively laminated on the one surface 11a of the transparent base material 11 in the above recited order.

Note that the first blackened layer, the metal layer, and the second blackened layer may also be laminated on both surfaces of the transparent base material 11. Specifically, as in a conductive substrate 20B shown in FIG. 2B, first blackened layers 131A and 131B, the metal layers 12A and 12B, and second blackened layers 132A and 132B may respectively be laminated on the one surface 11a and the other surface 11b of the transparent base material 11.

Note that in FIGS. 1B and 2B where the metal layer and the blackened layer are laminated on both surfaces of the transparent base material, the layers laminated above and below the transparent base material 11 are arranged to be symmetric with respect to the transparent base material 11. However, the present invention is not limited to such an arrangement. For example, in FIG. 2B, the layers laminated on the one surface 11a of the transparent base material 11 may alternatively have a configuration similar to that of FIG. 1A, having the metal layer 12 and the blackened layer 13 laminated in the above recited order, and in this way, the layers laminated above and below the transparent base material 11 may be asymmetric.

The conductive substrate according to the present embodiment has been described above. Because the conductive substrate according to the present embodiment has the metal layer and the blackened layer arranged on the transparent base material, light reflection by the metal layer can be controlled.

Although the extent of light reflection by the conductive substrate according to the present embodiment is not particularly limited, for example, when used as a conductive substrate for a touch panel, the blackened layer preferably has a relatively low average reflectance for light with a wavelength greater than or equal to 400 nm and less than or equal to 700 nm in order to control wiring visibility in the display. For example, the blackened layer preferably has an average reflectance less than or equal to 40%, more preferably less than or equal to 30%, and more preferably less than or equal to 20% for light with a wavelength greater than or equal to 400 nm and less than or equal to 700 nm.

The reflectance may be measured by irradiating light on the blackened layer of the conductive substrate. Specifically, for example, in the case where the metal layer 12 and the blackened layer 13 are successively laminated in the above recited order on the one surface 11a of the transparent base material 11 as shown in FIG. 1A, the reflectance can be measured by irradiating light on a surface A of the blackened layer 13. That is, light having a wavelength greater than or equal to 400 nm and less than or equal to 700 nm may be irradiated on the blackened layer 13 of the conductive substrate at 1 nm wavelength intervals to measure the reflectance, for example, and the average of the measured reflectance values may be regarded as the average reflectance of the blackened layer for light with a wavelength greater than or equal to 400 nm and less than or equal to 700 nm.

As described above, the conductive substrate according to the present embodiment can be suitably used as a conductive substrate for a touch panel, for example. In this case, a meshed wiring can be arranged on the conductive substrate, for example.

A conductive substrate having a meshed wiring can be obtained by etching the metal layer and the blackened layer of the above-described conductive substrate according to the present embodiment.

For example, the meshed wiring can be formed by two layers of wiring. A specific configuration example of the meshed wiring is shown in FIG. 3. FIG. 3 shows a conductive substrate 30 having a meshed wiring as viewed from an upper plane along the laminating direction of the metal layer and the blackened layer. The conductive substrate 30 shown in FIG. 3 has a transparent base material 11, and wirings 31A and 31B, the wiring 31A being parallel to the Y axis direction and the wiring 31B being parallel to the X axis direction of FIG. 3. The wirings 31A and 31B are formed by etching metal layers, and the upper surface and/or the lower surface of the wirings 31A and 31B have the blackened layers formed thereon (not shown). Note that the blackened layer is etched to be in the same shape as the wirings 31A and 31B.

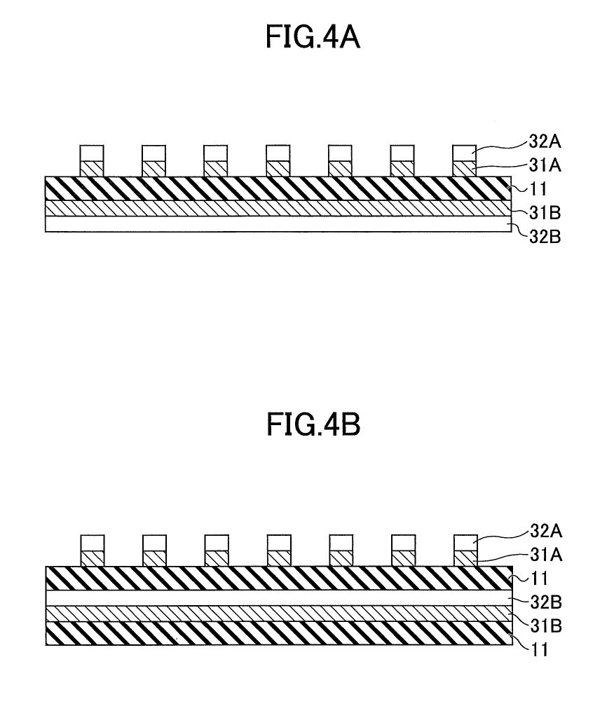

The arrangement of the transparent base material 11 and the wirings 31A and 31B is not particularly limited. FIGS. 4A and 4B show example arrangements of the transparent base material 11 and the wirings. FIGS. 4A and 4B are example cross-sectional views of the conductive substrate 30 across line A-A′ of FIG. 3.

First, as shown in FIG. 4A, the wirings 31A and 31B may respectively be arranged on the upper and lower surfaces of the transparent base material 11. In FIG. 4A, blackened layers 32A and 32B etched to be in the same shape as the wirings are respectively arranged on the upper surfaces of the wirings 31A and 31B.

Also, as shown in FIG. 4B, a pair of transparent base materials 11 may be used, the wirings 31A and 31B may respectively be arranged on the upper and lower surfaces of one of transparent base materials 11, and the wiring 31B may be interposed between the transparent base materials 11. Also, blackened layers 32A and 32B etched to be in the same shape as the wirings are respectively arranged on the upper surfaces of the wirings 31A and 31B. As described above, the arrangement of the blackened layer and the metal layer is not particularly limited. As such, for example, in FIGS. 4A and 4B, the arrangement order of the blackened layers 32A and 32B and the wirings 31A and 31B can be reversed. Further, for example, a plurality of blackened layers may be provided with respect to the wiring 31A and/or 31B.

Note, however, that the blackened layer is preferably arranged on the surface of the metal layer that is desirably controlled to limit light reflection. As such, for example, in the conductive substrate shown in FIG. 4B, if light reflection by the lower surfaces of the wirings 31A and 31B formed by metal layers need to be controlled, the positions of the blackened layers 32A and 32B and the positions of the wirings 31A and 31B may be reversed. Also, additional blackened layers may be provided between the transparent base materials 11 and the wirings 31A and 31B in addition to the blackened layers 32A and 32B, for example.

The conductive substrate having a meshed wiring as shown in FIGS. 3 and 4A may be formed from the conductive substrate as shown in FIG. 1B that has the metal layers 12A and 12B and the blackened layers 13A and 13B arranged on both surfaces of the transparent base material 11, for example.

In the case of using the conductive substrate as shown in FIG. 1B, first, the metal layer 12A and the blackened layer 13A on the one surface 11a of the transparent base material 11 are etched so that a plurality of linear patterns parallel to the Y axis direction in FIG. 1B are formed at predetermined intervals along the X axis direction. Note that the X axis direction in FIG. 1B corresponds to a direction parallel to the width direction of the layers. Also, the Y axis direction in FIG. 1B corresponds to a direction perpendicular to the paper surface of FIG. 1B.

Then, the metal layer 12B and the blackened layer 13B on the other surface 11b of the transparent base material 11 are etched so that a plurality of linear patterns parallel to the X axis direction in FIG. 1B are formed along the Y axis direction at predetermined intervals.

Through the above operations, a conductive substrate having a meshed wiring as shown in FIGS. 3 and 4A can be formed. Note that the surfaces of the transparent base material 11 may also be etched at the same time. That is, the metal layers 12A and 12B and the blackened layers 13A and 13B may be etched simultaneously. Also, a conductive substrate having the configuration as shown in FIG. 4A but additionally having blackened layers patterned into the same shape as those of the wirings 31A and 31B interposed between the transparent base material 11 and the wirings 31A and 31B may be fabricated by etching the conductive substrate as shown in FIG. 2B in a similar manner.

The conductive substrate having a meshed wiring as shown in FIG. 3 can also be formed using two conductive substrates as shown in FIG. 1A or 2A, for example. In the case of using two conductive substrates as shown in FIG. 1A, for example, the metal layers 12 and the blackened layers 13 of the two conductive substrates shown in FIG. 1A are etched so that a plurality of linear patterns parallel to the X axis direction are formed at predetermined intervals along the Y axis direction. Then, the two conductive substrates are bound together facing each other so that the linear patterns formed on the two conductive substrates by the above etching process intersect with each other to form the conductive substrate having a meshed wiring. The surfaces of the two conductive substrates that are to be bound together are not particularly limited. For example, the surface A of one of the conductive substrates as shown in FIG. 1A that is laminated with the metal layer 12 and the like and the other surface 11b of the other conductive substrate as shown in FIG. 1A that is not laminated with the metal layer 12 and the like may be bound together to fabricate a conductive substrate having a configuration as shown in FIG. 4B, for example.

The blackened layer is preferably arranged on the surface of the metal layer that is desirably controlled to limit light reflection. Thus, in the case where light reflection by the lower surface of the conductive substrate shown in FIG. 4B needs to be controlled, the positions of the blackened layers 32A and 32B and the positions of the wirings 31A and 31B are preferably reversed, for example. Also, additional blackened layers may be provided between the transparent base material 11 and the wirings 31A and 31B in addition to the blackened layers 32A and 32B, for example.

Also, for example, the two conductive substrates may be bound together such that the surfaces 11b of the transparent base materials 11 that are not laminated with the metal layers 12 and the like as shown in FIG. 1A are bonded to each other to have a cross-sectional configuration as shown in FIG. 4A.

Note that the widths and distances between the wirings of the conductive substrate having a meshed wiring as shown in FIGS. 3, 4A, and 4B are not particularly limited and can be selected in view of the amount of current flowing through the wirings, for example.

Also, although FIGS. 3, 4A, and 4B show examples of conductive substrates with meshed wirings (wiring patterns) that are formed by combining straight-line wirings, the present invention is not limited to such examples and the wirings configuring the meshed wiring pattern may be in any shape. For example, the wirings configuring the meshed wiring pattern may be arranged into jagged lines (zigzag lines) to prevent the occurrence of moiré patterns (interference patterns) between images on the display.

A conductive substrate having a meshed wiring that is made up of two layers of wiring as described above can be suitably used as a conductive substrate for a projected capacitive touch panel, for example.

(Conductive Substrate Fabrication Method)

In the following, an example method of fabricating a conductive substrate according to an embodiment of the present invention will be described.

The method of fabricating a conductive substrate according to the present embodiment may include a metal layer forming step of forming a metal layer on at least one surface of a transparent base material, and a blackened layer forming step of forming a blackened layer on at least one surface of the transparent base material.

In the blackened layer forming step, a blackened layer may be formed that contains elemental copper and/or a copper compound, and elemental nickel and a nickel compound, where the nickel compound includes a nickel oxide and a nickel hydroxide.

In the following, the method of fabricating a conductive substrate according to the present embodiment will be described. Note that the method of fabricating the conductive substrate can be suitably implemented to fabricate the above-described conductive substrate according to the present embodiment. Thus, the above-described features of the conductive substrate apply to the descriptions below except as otherwise specified and overlapping descriptions will be omitted.

As described above, in the conductive substrate according to the present embodiment, the order in which the metal layer and the blackened layer are laminated on the transparent base material is not particularly limited. Also, a plurality of metal layers and blackened layers may be formed. As such, the execution order of the metal layer forming step and the blackened layer forming step and the number of times these steps are executed are not particularly limited, and the number of times and execution timing may be adjusted in view of the structure of the conductive substrate to be formed, for example.

In the following, each of the above steps will be described.

First, the metal layer forming step will be described.

In the metal layer forming step, a metal layer may be formed on at least one surface of the transparent base material.

Note that the type of transparent base material on which the metal layer forming step or the blackened layer forming step is performed is not particularly limited, but as described above, a resin substrate (resin film) that transmits visible light or a glass substrate may be suitably used, for example. The transparent base material may be cut into a desired size beforehand if necessary.

As described above, the metal layer preferably includes a metal thin film layer. Also, the metal layer may include a metal thin film layer and a metal plating layer. Thus, the metal layer forming step may include a step of forming a metal thin film layer by a dry plating method, for example. Also, the metal layer forming step may include a step of forming a metal thin film layer by a dry plating method, and a step of forming a metal plating layer by an electroplating method, which is one type of wet plating method, using the metal thin film layer as a power feeding layer, for example.

Although the dry plating method used in the step of forming the metal thin film layer is not particularly limited, for example, a vapor deposition method, a sputtering method, or an ion plating method may be used. As an example of the vapor deposition method, a vacuum vapor deposition method can be suitably used, for example. Note that a sputtering method is more preferably used as the dry plating method in the step of forming the metal thin film layer in view of facilitating control of the film thickness.

The metal thin film layer can be suitably formed using a roll-to-roll sputtering apparatus, for example.

In the following, the step of forming a metal thin film layer in the case of using a roll-to-roll sputtering apparatus will be described as an example.

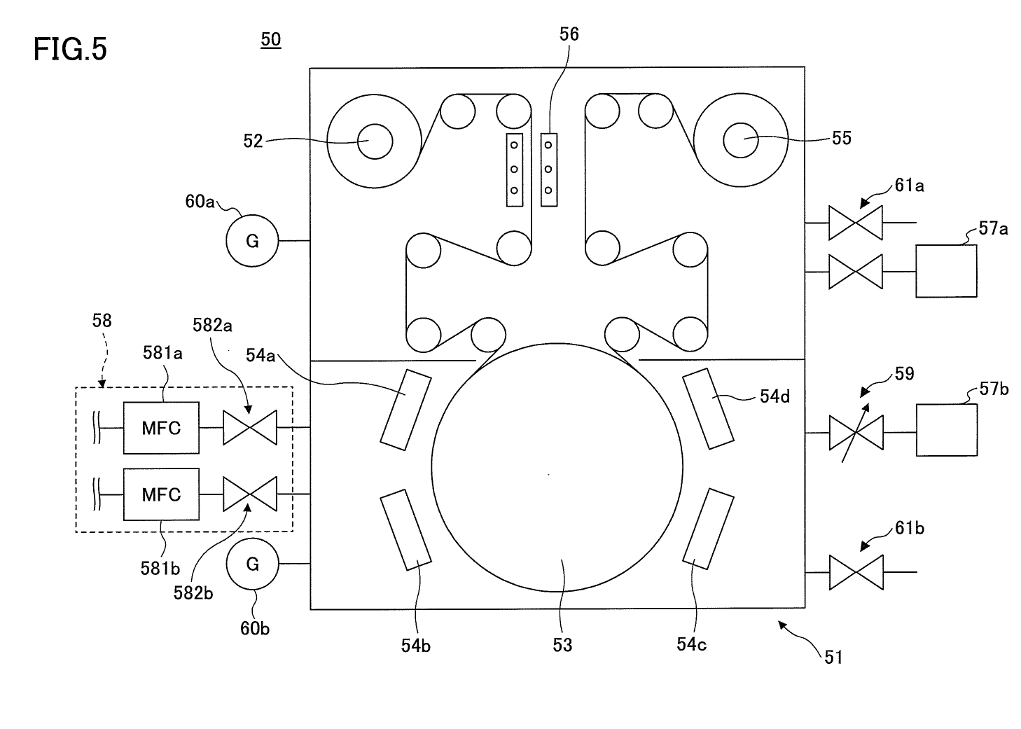

FIG. 5 shows an example configuration of a roll-to-roll sputtering apparatus 50.

The roll-to-roll sputtering apparatus 50 includes a housing 51 that houses most of its components.

The housing 51 accommodates an unwinding roll 52, a can roll 53, sputtering cathodes 54a-54d, and a winding roll 55, for example, as components for supplying a base material on which the metal thin film layer is to be formed. Also, guide rolls in addition to the above rolls and a heater 56 may optionally be provided along a conveying path of the base material on which the metal thin film layer is to be formed, for example.

The configuration of the can roll 53 is also not particularly limited. However, in a preferred example, a hard chromium plating may be applied to the surface of the can roll 53, and a coolant or a heating medium supplied from outside the housing 51 may be circulated within of the can roll 53 so that the temperature can be maintained substantially constant.

The sputtering cathodes 54a-54d are preferably magnetron sputtering cathodes that are arranged to face the can roll 53. Although the size of the sputtering cathodes 54a-54d is not particularly limited, the dimensions of the sputtering cathodes 54a-54d in the width direction of the base material on which the metal thin film layer is to be formed is preferably greater than the width of the base material.

The base material on which the metal thin film layer is to be formed is conveyed within the roll-to-roll sputtering apparatus 50, which is a roll-to-roll vacuum film forming apparatus, and the metal thin film layer is formed at the sputtering cathodes 54a-54d facing the can roll 53.

When forming the metal thin film layer using the roll-to-roll sputtering apparatus 50, a sputtering target may be loaded in the sputtering cathodes 54a-54d according to the composition of the metal thin film layer to be formed. Then, after the base material on which the metal thin film layer is to be formed is set to the unwinding roll 52 and the interior of the roll-to-roll sputtering apparatus 50 is evacuated by vacuum pumps 57a and 57b, a sputtering gas such as argon may be introduced into the housing 51 by a gas supply unit 58. Although the configuration of the gas supply unit 58 is not particularly limited, it may include a gas storage tank (not shown), for example. Also, mass flow controllers (MFCs) 581a and 581b and valves 582a and 582b may be provided between the gas storage tank and the housing 51 so that the amount of each gas supplied into the housing 51 can be controlled, for example. Although FIG. 5 shows an example where two sets of mass flow controllers and valves are provided, the number of the MFCs and valves to be installed is not particularly limited and can be selected in view of the number of types of gases used, for example. When supplying the sputtering gas into the housing 51, the flow rate of the sputtering gas and the opening degree of a pressure regulating valve 59 provided between the vacuum pump 57b and the housing 51 are preferably adjusted so that the pressure within the apparatus may be maintained greater than or equal to 0.13 Pa and less than or equal to 1.3 Pa when forming the metal thin film layer.

In such a state, sputtering discharge is performed by supplying power from a sputtering DC power supply connected to the sputtering cathodes 54a-54d while conveying the base material from the unwinding roll 52 at a speed of 0.5 m/min to 10 m/min, for example. In this way, a desired metal thin film layer can be continuously formed on the base material.

Note that the above-described roll-to-roll sputtering apparatus 50 may include components other than those described above. For example, as shown in FIG. 5, the roll-to-roll sputtering apparatus 50 may additionally include vacuum gauges 60a and 60b for measuring the degree of vacuum within the housing 51 and vent valves 61a and 61b.

In the following, the step of forming a metal plating layer will be described. Conditions for the step of forming the metal plating layer by a wet plating method, namely, electroplating process conditions, are not particularly limited, and various conditions for routine methods may be adopted. For example, a metal plating layer can be formed by supplying a base material having a metal thin film layer formed thereon in a plating tank containing a metal plating solution, and the metal plating layer can be formed by controlling the current density and the conveying speed of the base material.

In the following, the blackened layer forming step will be described.

As described above, the blackened layer forming step is a step of forming a blackened layer on at least one surface of the transparent base material. The method for forming the blackened layer is not particularly limited, but a sputtering method can be suitably used. That is, using a sputtering method facilitates formation of a layer containing elemental copper and/or a copper compound, and elemental nickel and a nickel compound, where the nickel compound includes a nickel oxide and a nickel hydroxide.

In the case of forming a blackened layer by a sputtering method, for example, the roll-to-roll sputtering apparatus 50 described above can be used. Because the configuration of the roll-to-roll sputtering apparatus 50 is described above, its description is hereby omitted.

In the case of forming a blackened layer using the roll-to-roll sputtering apparatus 50, for example, a sputtering target corresponding to an alloy containing nickel and copper may be loaded in the sputtering cathodes 54a-54d. Then, the base material on which the blackened layer is to be famed is set to the unwinding roll 52 and the interior of the apparatus is evacuated by the vacuum pumps 57a and 57b.

Then, a sputtering gas containing oxygen gas and water vapor is introduced into the housing 51 by the gas supply unit 58. At this time, the flow rate of the sputtering gas and the degree of opening of the pressure regulating valve 59 provided between the vacuum pump 57b and the housing 51 are preferably adjusted so that the internal pressure of the apparatus may be maintained greater than or equal to 0.13 Pa and less than or equal to 13 Pa when performing film formation.

Note that in order to facilitate adjustment of the amounts of oxygen and water vapor supplied to the blackened layer, inert gas, oxygen gas, and water vapor are preferably supplied to the housing 51 simultaneously and their respective partial pressures are adjusted. Thus, the sputtering gas preferably contains an inert gas, oxygen gas, and water vapor. Although the type of inert gas used is not particularly limited, argon or helium can be suitably used, for example. Also, the water vapor can be supplied as gas mixture of the inert gas and water, for example.

The ratio of oxygen gas to water vapor contained in the sputtering gas is not particularly limited and can be selected in view of the composition of the blackened layer to be formed, for example.

In a preferred example, nickel hydroxide may be contained in the blackened layer to such an extent that it can be identified as a peak for nickel hydroxide when the blackened layer that has been formed is measured by X-ray photoelectron spectroscopy (XPS).

In particular, when the blackened layer is measured by X-ray photoelectron spectroscopy (XPS), the following Ni 2p3/2 spectrum peak intensity ratio is preferably exhibited. Provided the peak intensity of elemental nickel is 100, the peak intensity of nickel oxide is preferably greater than or equal to 70 and less than or equal to 80, and the peak intensity of nickel hydroxide is preferably greater than or equal to 65. Thus, the supply amount of each gas is preferably adjusted so that the above peak intensity ratio can be obtained upon measuring the blackened layer that has been formed by X-ray photoelectron spectroscopy (XPS).

Also, the arrangement of the gas supply pipes for supplying the gases are preferably adjusted so that when forming the blackened layer, the ratios of the nickel oxide and the nickel hydroxide with respect to elemental nickel contained in the blackened layer may be within the above desired ranges across the entire width of the conductive substrate, for example.

In such a state, sputtering discharge is performed by supplying power from a sputtering DC power source connected to the sputtering cathodes 54a-54d while conveying the base material from the unwinding roll 52 at a speed of 0.5 m/min to 10 m/min, for example. In this way, a desired blackened layer may be continuously formed on the base material.

The conductive substrate obtained by implementing the above-described method of fabricating a conductive substrate may be arranged into a conductive substrate having a meshed wiring. In this case, in addition to the above steps, the method may further include an etching step for etching the metal layer and the blackened layer to form the wiring.

In the etching process, for example, first, a resist having openings corresponding to portions to be removed by etching is formed on the outermost surface of the conductive substrate. For example, in the case of etching the conductive substrate shown in FIG. 1A, the resist can be formed on the surface A exposing the blackened layer 13 arranged on the conductive substrate. Note that the method of forming the resist having openings corresponding to portions to be removed by etching is not particularly limited and a conventional technique such as photolithography may be used to form the resist, for example.

Then, by supplying an etching solution from above the resist, the metal layer 12 and the blackened layer 13 can be etched.

When the metal layer and the blackened layer are arranged on both surfaces of the transparent base material 11 as shown in FIG. 1B, for example, resists having openings of predetermined shapes may be formed on the outermost surfaces A and B of the conductive substrate, and the metal layers 12A and 12B and the blackened layers 13A and 13B formed on the two surfaces of the transparent base 11 may be etched simultaneously.

Also, etching of the metal layers 12A and 12B and the blackened layers 13A and 13B formed on the two surfaces of the transparent base material 11 can be performed one surface at a time. That is, for example, etching of the metal layer 12B and the blackened layer 13B can be performed after etching the metal layer 12A and the blackened layer 13A.

The blackened layer formed on the conductive substrate according to the present embodiment exhibits reactivity to an etching solution similar to that of the metal layer, and as such, the etching solution used in the etching step is not particularly limited and an etching solution generally used for etching a metal layer can be suitably used, for example. More preferably, a mixed aqueous solution of ferric chloride and hydrochloric acid can be used, for example. Although the content of ferric chloride and hydrochloric acid in the etching solution is not particularly limited, for example, ferric chloride is preferably contained at a percentage greater than or equal to 5 wt % and less than or equal to 50 wt %, and more preferably greater than or equal to 10 wt % and less than or equal to 30 wt %. Further, the etching solution preferably contains hydrochloric acid at a percentage greater than or equal to 1 wt % and less than or equal to 50 wt %, and more preferably greater than or equal to 1 wt % and less than or equal to 20 wt %, for example. Note that the remaining content of the etching solution may be water, for example.

Although the etching solution can be used at room temperature, the etching solution is preferably heated to enhance reactivity. For example, the etching solution may be heated to a temperature greater than or equal to 40° C. and less than or equal to 50° C.

Note that the specific form of the meshed wiring obtained by the above-described etching step may be as described above such that a description thereof will be omitted.

Also, in the case of forming the conductive substrate having a meshed wiring by bonding together two conductive substrates each having a metal layer and a blackened layer arranged on one surface of the transparent base material 11 as shown in FIG. 1A or 2A, a step of bonding together the conductive substrates may be further implemented, for example. In this case, the method of bonding together the two conductive substrates is not particularly limited, and for example, the conductive substrates may be bonded together using adhesive.

A conductive substrate and a method of fabricating a conductive substrate according to embodiments of the present invention have been described above. The conductive substrate according to the present embodiment has a blackened layer that has desirably high reactivity to an etching solution such that the metal layer and the blackened layer can have substantially the same reactivity to the etching solution. In this way, even when the metal layer and the blackened layer are etched simultaneously, the metal layer and the blackened layer can be patterned into desired shapes, and dimensional variations can be controlled. Thus, the metal layer and the blackened layer can be etched simultaneously.

Also, the blackened layer can limit light reflection by the metal layer. For example, when used as a conductive substrate for a touch panel, light reflection at a wiring surface can be reduced and visibility of the display can be enhanced.

### EXAMPLES

In the following, specific examples of the present invention and comparative examples will be described. Note, however, that the present invention is not limited to these examples.

(Evaluation Method)

Samples prepared in the examples and comparative examples were evaluated by the following method.

(1) Measurement by X-Ray Photoelectron Spectroscopy (XPS)

Measurements were made using an X-ray photoelectron spectroscope (manufactured by PHI, model: Quantera SXM). Note that an Al monochromatic X-ray source (1486.6 eV) was used as the X-ray source.

As described below, in each of the following examples and comparative examples, a conductive substrate having a structure as shown in FIG. 2A was fabricated. Then, the surface 132a of the conductive substrate exposing the second blackened layer 132 in FIG. 2A was subjected to Ar ion etching, and the Ni 2p3/2 spectrum was measured 10 nm from the outermost surface of the conductive substrate. Based on the measured spectrum, the peak heights (intensities) of nickel oxide and nickel hydroxide were calculated, on the premise that the peak height (intensity) of elemental nickel, namely, metallic nickel, is 100.

(2) Measurement of Reflectance

The reflectance of the blackened layer for specular reflection of light in the wavelength range of 400 nm to 700 nm at a 5° angle of incidence was measured using a spectrophotometer (manufactured by Shimadzu Corporation, model: UV-2600) and the average reflectance was calculated based thereon. In measuring the reflectance, light in the above wavelength range was irradiated while changing the wavelength at 1 nm intervals and the reflectance at each wavelength was measured. Then, the average of the measured reflectance values was obtained as the average reflectance of the blackened layer for light in the wavelength range of 400 nm to 700 nm.

In each of the following examples and comparative examples, a conductive substrate having the structure as shown in FIG. 2A was fabricated. As such, the average reflectance for light in the wavelength range of 400 nm to 700 nm was measured and calculated with respect to the surface 132a exposing the second blackened layer 132 as shown in FIG. 2A. Note that in Table 1 shown below, “reflectance” indicates the average reflectance of the blackened layer for light in the wavelength range of 400 nm to 700 nm measured and calculated with respect to each of the examples and comparative examples.

(3) Etching Test

In an etching test, an etching solution containing ferric chloride at 10 wt %, hydrochloric acid at 1 wt %, and water as the remaining component was used.

The conductive substrate fabricated in each of the examples and comparative examples was immersed in an etching solution at a temperature of 25° C. for 60 seconds without forming a resist or the like and then taken out of the etching solution. Thereafter, the conductive substrate was thoroughly rinsed with water to remove the etching solution adhered to the conductive substrate.

The conductive substrate that has been immersed in the etching solution and rinsed with water thereafter was visually observed to see whether the metal layer and the blackened layer were remaining on the transparent base material.

When the metal layer and the blackened layer do not remain, that is, when no residue can be observed, this means that the conductive substrate includes a metal layer and a blackened layer that can be etched simultaneously. On the other hand, when at least one of the metal layer and the blackened layer remains, that is, when a residue can be observed, this means that the metal layer and the blackened layer of the conductive substrate cannot be etched simultaneously.

(Sample Fabrication Conditions)

As examples and comparative examples, conductive substrates were prepared under the conditions described below and evaluated by the above-described evaluation methods.

### Example 1

A conductive substrate having the structure shown in FIG. 2A was fabricated.

(Blackened Layer Forming Step)

First, a transparent base material made of polyethylene terephthalate resin (PET) having a width of 500 mm and a thickness of 100 μm was set to the unwinding roll 52 of the roll-to-roll sputtering apparatus 50 shown in FIG. 5. The total luminous transmittance of the transparent base material made of PET was 97% upon determining the total luminous transmittance of the transparent base material using the method prescribed in JIS K 7361-1.

Further, a sputtering target of a nickel-copper alloy containing nickel at 65 wt % and copper at 35 wt % was set to the sputtering cathodes 54a-54d.

Then, the heater 56 of the roll-to-roll sputtering apparatus 50 was heated to 100° C., and the transparent base material was heated to remove water contained in the base material.

Then, the interior of the housing 51 was evacuated to 1×10⁻⁴ Pa, after which argon gas, oxygen gas, and water vapor were introduced into the housing 51. Note that the water vapor was introduced as argon gas containing saturated water at room temperature. The argon gas, the oxygen gas, and the argon gas containing water (argon-water gas mixture) were supplied to the housing 51 in the amounts specified in Table 1 shown below, and the pressure within the housing 51 was adjusted to 2 Pa.

Then, sputtering discharge was performed by supplying power from a sputtering DC power source connected to the sputtering cathodes 54a-54d while conveying the transparent base material from the unwinding roll 52 at a speed of 2 m/min to continuously form a blackened layer on the transparent base material. By performing such operation, the first blackened layer 131 with a thickness of 50 nm was formed on the transparent base material.

Note that when forming the first blackened layer, sputtering was performed by introducing argon gas, oxygen gas, and water vapor into the housing 51 using a nickel-copper alloy as the sputtering target as described above. As such, the first blackened layer contains elemental copper and/or a copper compound, and elemental nickel and a nickel compound.

(Metal Layer Forming Step)

Then, the transparent base material having the first blackened layer formed thereon was set to the unwinding roll 52, and the sputtering target set in the sputtering cathodes 54a-54d was changed to a copper sputtering target. Then, after evacuating the interior of the housing 51 of the roll-to-roll sputtering apparatus 50 to 1×10⁻⁴ Pa, an operation similar to the above operation for forming the first blackened layer was performed, aside from supplying only argon gas into the housing 51 and adjusting the pressure within the housing 51 to 0.3 Pa, and in this way, a copper layer having a thickness of 20 nm was formed as the metal layer on the upper surface of the first blackened layer.

(Blackened Layer Forming Step)

Then, the transparent base material having the first blackened layer and the metal layer formed thereon was set to the unwinding roll 52, and the second blackened layer 132 was formed on the upper surface of the metal layer 12 by performing a film forming operation under the same conditions as that for forming the first blackened layer 131.

The conductive substrate sample that has been fabricated was then subjected to measurement by X-ray photoelectron spectroscopy (XPS), reflectance measurement, and the etching test, the results of which are indicated in Table 1 shown below.

### Example 2 to Example 4

Conductive substrates were fabricated in a manner similar to Example 1, aside from adjusting the flow rates of argon gas, oxygen gas, and argon gas containing water (argon-water gas mixture) to be supplied to the housing 51 at the time of forming the first blackened layer and the second blackened layer to the values indicated in Table 1, and the conductive substrates were evaluated by the above evaluation methods.

The results of the evaluations are indicated in Table 1 shown below.

### Comparative Example 1

A conductive substrate was fabricated in a manner similar to Example 1, aside from adjusting the flow rates of argon gas and oxygen gas to be supplied to the housing 51 at the time of forming the first blackened layer and the second blackened layer to the values indicated in Table 1, and not supplying the argon gas containing water (argon-water gas mixture). Also, the above-described evaluations were performed on the fabricated conductive substrate.

The results of the evaluations are indicated in Table 1 shown below.

TABLE 1

| | SPUTTERING GAS | | | XPS MEASUREMENT | | | |
|---|---|---|---|---|---|---|---|
| | FLOW RATE (sccm) | | | NICKEL | NICKEL | | |
| | | | ARGON- | OXIDE | HYDROXIDE | | |
| | OXYGEN | ARGON | WATER GAS | PEAK | PEAK | | ETCHING |
| | GAS | GAS | MIXTURE | INTENSITY | INTENSITY | REFLECTANCE | TEST |
| EXAMPLE 1 | 55 | 440 | 5 | 79 | 66 | 20.5% | NO |
| | | | | | | | RESIDUE |
| EXAMPLE 2 | 55 | 430 | 15 | 80 | 70 | 19.8% | NO |
| | | | | | | | RESIDUE |
| EXAMPLE 3 | 50 | 440 | 10 | 78 | 75 | 22.2% | NO |
| | | | | | | | RESIDUE |
| EXAMPLE 4 | 30 | 465 | 5 | 70 | 65 | 40.0% | NO |
| | | | | | | | RESIDUE |
| COMPARATIVE | 60 | 440 | 0 | 81 | 58 | 21.4% | RESIDUE |
| EXAMPLE 1 | | | | | | | REMAINS |

Based on the evaluation results indicated in Table 1, it can be appreciated that upon evaluating the blackened layers of the samples of Examples 1 to 4 by X-ray photoelectron spectroscopy, peaks of elemental nickel, nickel oxide, and nickel hydroxide could be observed, thereby indicating that the samples contain the above components.

In contrast, no clear peak of nickel hydroxide could be observed from the sample of Comparative Example 1. Note that for Comparative Example 1, the peak intensity of nickel hydroxide is 58, where the peak intensity of elemental nickel is 100. This value indicates the intensity of XPS measurement data at the peak position of nickel hydroxide and corresponds to a baseline intensity.

As can be appreciated from Table 1, with respect to Examples 1 to 4, the ratios of the peak intensities of nickel oxide and nickel hydroxide are respectively greater than or equal to 70 and less than or equal to 80 for nickel oxide and greater than or equal to 65 for nickel hydroxide, where the peak intensity of elemental nickel is 100.

Also, upon performing etching tests on the conductive substrates of Examples 1 to 4, no residue of the blackened layer and the metal layer was observed on the PET film of any of the samples after the etching was performed. As such, it could be confirmed that the blackened layer of each of the above samples exhibits good etching properties such that the blackened layer and the metal layer can be etched simultaneously.

Also, in each of the conductive substrate samples of Examples 1 to 4, the average reflectance of the blackened layer for light with a wavelength range of 400 nm to 700 nm was less than or equal to 40.0%, indicating that the blackened layer could adequately control light reflection at the surface of the metal layer.

On the other hand, upon performing the etching test on the conductive substrate of Comparative Example 1, residue of the blackened layer was observed on the PET film. This indicates that the blackened layer formed on the conductive substrate of Comparative Example 1 has low reactivity to the etching solution such that the blackened layer and the metal layer cannot be etched simultaneously.

It can be appreciated from the above evaluation results that the blackened layer exhibits desirably high reactivity to an etching solution in the case where the blackened layer contains elemental copper and/or a copper compound, and elemental nickel and a nickel compound, where the nickel compound contains a nickel oxide and nickel hydroxide. Further, it can be appreciated that when the blackened layer contains the above components, the blackened layer and the metal layer can be etched simultaneously.

Although the conductive substrate according to the present invention has been described above with respect to certain illustrative embodiments and examples, the present invention is not limited to the above embodiments and examples, and various modifications and changes can be made within the scope of the present invention.

The present application is based on and claims the benefit of priority of Japanese Patent Application No. 2015-091714 filed on Apr. 28, 2015, the entire contents of which are herein incorporated by reference.

### DESCRIPTION OF THE REFERENCE NUMERALS

10A, 10B, 20A, 20B, 30 conductive substrate
11 transparent base material
12, 12A, 12B metal layer
13, 13A, 13B, 131, 132, 131A, 131B, 132A, 132B, 32A, 32B blackened layer
   31A, 31B wiring

1. A conductive substrate comprising:
a transparent base material;
a metal layer formed on at least one surface of the transparent base material; and
a blackened layer formed on at least one surface of the transparent base material;
wherein the blackened layer contains elemental copper and/or a copper compound and elemental nickel and a nickel compound; and
wherein the nickel compound includes a nickel oxide and a nickel hydroxide.

2. The conductive substrate according to claim 1, wherein
when the blackened layer is measured by X-ray photoelectron spectroscopy, the blackened layer exhibits a Ni 2p3/2 spectrum peak intensity ratio in which, provided the peak intensity of elemental nickel is 100, the peak intensity of nickel oxide is greater than or equal to 70 and less than or equal to 80, and the peak intensity of nickel hydroxide is greater than or equal to 65.

3. The conductive substrate according to claim 1,
wherein the metal layer contains copper.

4. The conductive substrate according to claim 1, wherein the metal layer and the blackened layer are successively formed on the at least one surface of the transparent base material from the transparent base material side.

5. The conductive substrate according to claim 1, wherein the blackened layer, the metal layer, and the blackened layer are successively formed on the at least one surface of the transparent base material from the transparent base material side.

6. The conductive substrate according to claim 1, wherein the blackened layer has a thickness less than or equal to 100 nm.

7. The conductive substrate according to claim 1, wherein the blackened layer has an average reflectance less than or equal to 40% for light with a wavelength greater than or equal to 400 nm and less than or equal to 700 nm.

8. The conductive substrate according to claim 1, further comprising a meshed wiring.
